(19) United States
(12) Patent Application Publication
(10) Pub. No.: US 2025/0203762 A1
(43) Pub. Date: Jun. 19, 2025

(54) SEMICONDUCTOR DEVICE

(71) Applicant: SAMSUNG ELECTRONICS CO., LTD., Suwon-si (KR)

(72) Inventors: Dongkyun KIM, Suwon-si (KR); Sungchan KANG, Suwon-si (KR); Daehyuk SON, Suwon-si (KR); Hotaik LEE, Suwon-si (KR); Seogwoo HONG, Suwon-si (KR)

(73) Assignee: SAMSUNG ELECTRONICS CO., LTD., Suwon-si (KR)

(21) Appl. No.: 18/795,871

(22) Filed: Aug. 6, 2024

(30) Foreign Application Priority Data
Dec. 15, 2023 (KR) 10-2023-0183045

(51) Int. Cl. H05K 1/02; H05K 1/18

(52) U.S. Cl. CPC H05K 1/0272; H05K 1/184; H05K 2201/064; H05K 2201/10287

(57) ABSTRACT

Provided is a semiconductor device including a semiconductor chip including a substrate, the substrate extending along a plane; a plurality of coolant chambers spaced apart from the substrate at a certain distance in a first direction, each coolant chamber of the plurality of coolant chambers being configured to accommodate a coolant, the first direction being perpendicular to the plane; a plurality of nozzles respectively provided on or below the plurality of coolant chambers and configured to spray the coolant toward the substrate; and a plurality of actuators respectively provided on the plurality of coolant chambers and configured to individually adjust internal pressures of the plurality of coolant chambers.

### CROSS-REFERENCE TO RELATED APPLICATION

This application is based on and claims priority under 35 U.S.C. § 119 to Korean Patent Application No. 10-2023-0183045, filed on Dec. 15, 2023, in the Korean Intellectual Property Office, the disclosure of which is incorporated by reference herein in its entirety.

### BACKGROUND

### 1. Field

One or more example embodiments of the disclosure relate to a semiconductor device including a cooling structure.

### 2. Description of the Related Art

Air cooling devices have been mainly used to remove heat generated in electronic devices. As the power density of electronic devices has gradually increased, liquid cooling devices have been widely used to respond to the increased heat generation amount. Moreover, there has been a rising interest in next-generation cooling methods with high efficiency, such as liquid cooling devices, to reduce power consumption in data centers.

Components which generate heat in an electronic device may be diversified. In addition, the diversified components may be arranged in various positions in an electronic device. As the diversified components may be arranged in different positions in an electronic device, temperature ranges may be differentiated according to heating areas. When different cooling structures are arranged in correspondence to heating areas having different temperature ranges, the cooling efficiency may be improved.

### SUMMARY

One or more example embodiments of the disclosure provide a semiconductor device employing a liquid cooling structure.

One or more example embodiments of the disclosure provide a semiconductor device including a cooling structure having different cooling capacities corresponding to heating areas having different temperature ranges.

One or more example embodiments of the disclosure provide a semiconductor device having improved cooling efficiency by including a cooling structure having different cooling capacities corresponding to heating areas having different temperature ranges.

One or more example embodiments of the disclosure provide a semiconductor device having improved energy efficiency by including a cooling structure individually operating in correspondence to heating areas having different temperature ranges.

Additional aspects will be set forth in part in the description which follows and, in part, will be apparent from the description, or may be learned by practice of the presented embodiments of the disclosure.

According to an aspect of an example embodiment of the disclosure, a semiconductor device includes a semiconductor chip including a substrate, the substrate extending along a plane; a plurality of coolant chambers spaced apart from the substrate at a certain distance in a first direction, each coolant chamber of the plurality of coolant chambers being configured to accommodate a coolant, the first direction being perpendicular to the plane; a plurality of nozzles respectively provided on or below the plurality of coolant chambers and configured to spray the coolant toward the substrate; and a plurality of actuators respectively provided on the plurality of coolant chambers and configured to individually adjust internal pressures of the plurality of coolant chambers.

The plurality of coolant chambers may be spaced apart from each other along a direction parallel to the plane.

The semiconductor chip may include a plurality of cooling areas along the plane, and each cooling area of the plurality of cooling areas may have a surface area of about 0.25 mm² to about 30 mm².

The semiconductor chip may be divided into a plurality of cooling areas, each cooling area having a certain length in a second direction and a certain width in a third direction, to correspond to each nozzle included in the plurality of nozzles, the second direction being perpendicular to the first direction and the third direction being perpendicular to the first direction and the second direction.

The certain length of each cooling area of the plurality of cooling areas in the second direction may be about 3 mm to about 20 mm, and the certain width of each cooling area of the plurality of cooling areas in the third direction may be about 1 mm to about 18 mm.

A heating component included in the semiconductor chip may be positioned to correspond to at least one of the plurality of cooling areas.

The plurality of actuators may be further configured to adjust an internal pressure of a corresponding coolant chamber based on a first heating temperature of a first cooling area of the plurality of cooling areas and a second heating temperature of a second cooling area of the plurality of cooling areas.

The plurality of actuators may be further configured to adjust the internal pressure of the corresponding coolant chamber based on a difference between the first heating temperature and the second heating temperature being about 10° C. to about 30° C.

The semiconductor device may further include: a sensor configured to measure temperatures of the plurality of cooling areas; and a controller configured to control operations of the plurality of actuators based on temperature information measured by the sensor.

The semiconductor device may further include: a coolant inflow port through which the coolant is introduced; a coolant inflow channel configured to have a fluid communication with each coolant chamber of the plurality of coolant chambers and introduce the coolant, introduced through the coolant inflow port, into the plurality of coolant chambers; and a pump configured to apply a pressure to the coolant passing through the coolant inflow channel.

The coolant inflow channel may include a plurality of coolant inflow channels, and the plurality of coolant inflow channels may include: a first coolant inflow channel configured to have a fluid communication with a plurality of first coolant chambers arranged in a second direction, the second direction being perpendicular to the first direction; and a second coolant inflow channel configured to have a fluid communication with a plurality of second coolant chambers arranged apart from the plurality of first coolant chambers in a third direction, the third direction being perpendicular to the second direction.

The coolant may be sprayed toward a coolant spray area between the plurality of coolant chambers and the semiconductor chip, and the semiconductor device may further include: a coolant discharge channel configured to have a fluid communication with the coolant spray area and discharge the coolant from the coolant spray area; and a pump configured to apply a pressure to the coolant passing through the coolant discharge channel.

The plurality of actuators may include piezoelectric actuators, and the semiconductor device may further include a plurality of diaphragms respectively provided between the plurality of actuators and the plurality of coolant chambers.

The plurality of actuators may include thermal-jet actuators.

The plurality of coolant chambers may include a plurality of first coolant chambers, arranged to face a first surface of the semiconductor chip, and a plurality of second coolant chambers, arranged to face a second surface of the semiconductor chip, the second surface being opposite to the first surface. The plurality of nozzles may include a plurality of first nozzles, provided respectively corresponding to the plurality of first coolant chambers to spray a first coolant toward the first surface of the semiconductor chip, and a plurality of second nozzles, provided respectively corresponding to the plurality of second coolant chambers to spray a second coolant toward the second surface of the semiconductor chip. The plurality of actuators include a plurality of first actuators, provided respectively corresponding to the plurality of first coolant chambers and configured to individually adjust internal pressures of the plurality of first coolant chambers, and a plurality of second actuators, provided respectively corresponding to the plurality of second coolant chambers and configured to individually adjust internal pressures of the plurality of second coolant chambers.

The semiconductor device may further include: a printed circuit board arranged to face the second surface of the semiconductor chip; a through hole provided between the printed circuit board and the semiconductor chip; and a wiring provided in the through hole and configured to electrically connect the printed circuit board to the semiconductor chip.

The semiconductor device may further include: a coolant inflow port through which the coolant is introduced; a coolant inflow channel configured to have a fluid communication with the plurality of first coolant chambers and the plurality of second coolant chambers and introduce the coolant, introduced through the coolant inflow port, into the plurality of first coolant chambers and the plurality of second coolant chambers; and a pump configured to apply a pressure to the coolant passing through the coolant inflow channel.

The first surface of the semiconductor chip may be divided into a plurality of first cooling areas, each first cooling area having a length in a second direction and a width in a third direction, to correspond to each first nozzle included in the plurality of first nozzles, the second direction being perpendicular to the first direction and the third direction being perpendicular to the first direction and the second direction. The second surface of the semiconductor chip may be divided into a plurality of second cooling areas, each second cooling area having a length in the second direction and a width in the third direction, to correspond to each second nozzle included in the plurality of second nozzles.

The semiconductor device may further include: a sensor configured to measure a temperature of each first cooling area of the plurality of first cooling areas and each second cooling area of the plurality of second cooling areas; and a controller configured to control operations of the plurality of first actuators and the plurality of second actuators based on temperature information measured by the sensor.

The first coolant may be sprayed toward a first coolant spray area between the plurality of first coolant chambers and the semiconductor chip, and the second coolant may be sprayed toward a second coolant spray area between the plurality of second coolant chambers and the semiconductor chip. The semiconductor device may further include: a coolant discharge channel configured to have a fluid communication with the first coolant spray area and the second coolant spray area and discharge the first coolant and the second coolant from the first coolant spray area and the second coolant spray area; and a pump configured to apply a pressure to the first coolant and the second coolant passing through the coolant discharge channel.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is an exploded perspective view of a semiconductor device according to an example embodiment;

FIG. 2 is a plan view of a semiconductor device according to an example embodiment;

FIG. 3 is a cross-sectional view of a semiconductor device of FIG. 2 taken along line A-A;

FIG. 4 is a cross-sectional view of a semiconductor device of FIG. 2 taken along line B-B;

FIG. 5 is a cross-sectional view of a semiconductor device of FIG. 2 taken along line C-C;

FIGS. 6A to 6C are each a schematic view of an actuator, a sensor, and a controller according to example embodiments;

FIG. 7 is a cross-sectional view of a semiconductor device of FIG. 2 taken along line A-A;

FIG. 8 is a schematic view of an actuator, a sensor, and a controller according to an example embodiment;

FIG. 9 is an exploded perspective view of a semiconductor device according to an example embodiment;

FIG. 10 is a cross-sectional view of a semiconductor device according to an example embodiment;

FIG. 11 is an exploded perspective view of a semiconductor device according to an example embodiment; and

FIG. 12 is a cross-sectional view of a semiconductor device according to an example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, example embodiments will be described in detail with reference to the accompanying drawings. In the drawings, like reference numerals in the drawings denote like elements, and sizes of components in the drawings may be exaggerated for clarity and convenience of explanation. Meanwhile, embodiments described below are provided only as an example, and thus can be embodied in various forms. It will be understood that when a component is referred to as being “on” or “over” another component, the component can be directly on, under, on the left of, or on the right of the other component, or can be on, under, on the left of, or on the right of the other component in a non-contact manner. An expression used in the singular encompasses the expression of the plural, unless it has a clearly different meaning in the context. When a portion “includes” an element, another element may be further included, rather than excluding the existence of the other element, unless otherwise described. The use of the terms “a” and “an” and “the” and similar referents in the context of describing embodiments (especially in the context of the following claims) are to be construed to cover both the singular and the plural. The operations of all methods described herein can be performed in any suitable order unless otherwise indicated herein or otherwise clearly contradicted by context, and embodiments are not limited to the described order of the operations. Moreover, the terms “part,” “module,” etc. refer to a unit processing at least one function or operation, and may be implemented by a hardware, a software, or a combination thereof. The connecting lines, or connectors shown in the various figures presented are intended to represent exemplary functional relationships and/or physical or logical couplings between the various elements, and thus it should be noted that many alternative or additional functional relationships, physical connections or logical connections may be present in a practical device. The use of any and all examples, or exemplary language provided herein, is intended merely to better illuminate technical ideas and does not pose a limitation on the scope of embodiments unless otherwise claimed.

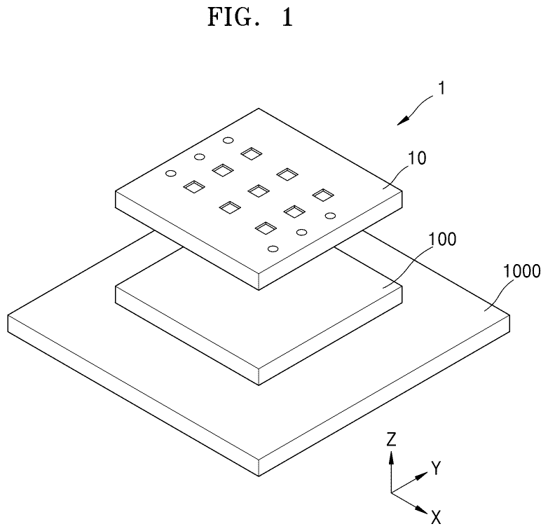

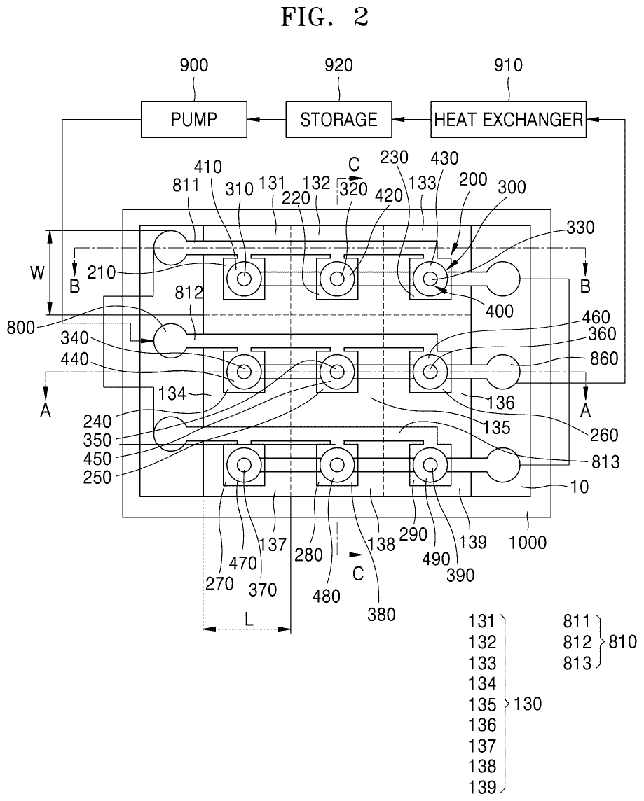

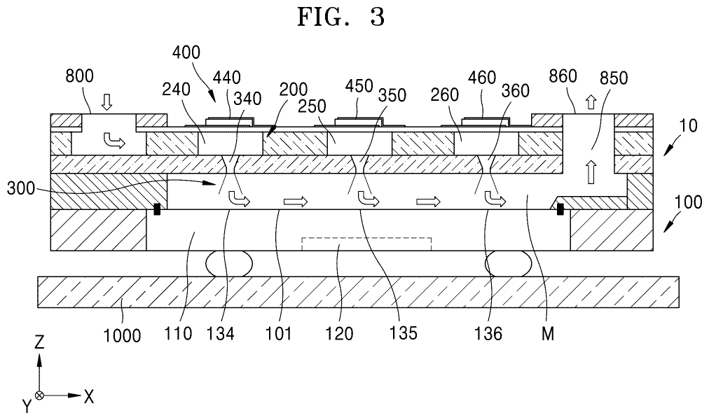

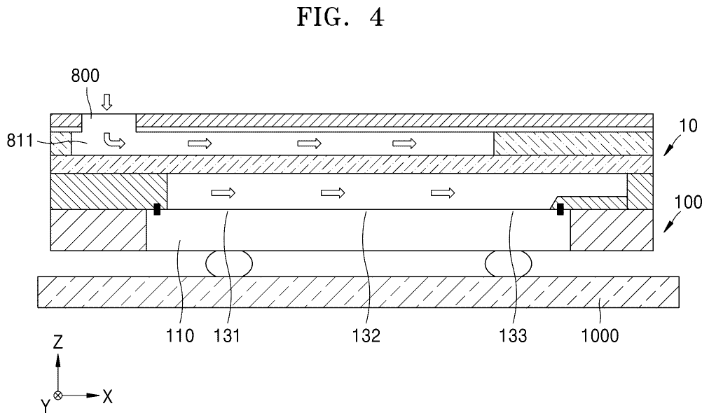

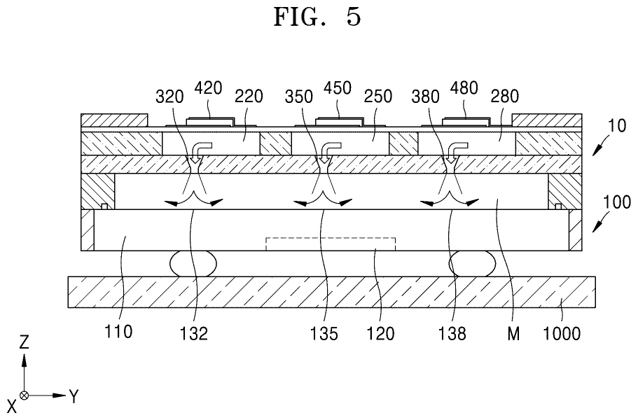

FIG. 1 is an exploded perspective view of a semiconductor device according to an example embodiment. FIG. 2 is a plan view of a semiconductor device according to an example embodiment. FIG. 3 is a cross-sectional view of a semiconductor device of FIG. 2 taken along line A-A. FIG. 4 is a cross-sectional view of a semiconductor device of FIG. 2 taken along line B-B. FIG. 5 is a cross-sectional view of a semiconductor device of FIG. 2 taken along line C-C.

Referring to FIGS. 1 and 2, a semiconductor device 1 according to an example embodiment may include a semiconductor chip 100 including a substrate 110 (see FIGS. 3, 4, 5) extending along a plane (e.g., XY plane). According to an embodiment, in the semiconductor device 1 including the semiconductor chip 100, the performance of the semiconductor device 1 may be limited by heat generated from the semiconductor chip 100. To address a heating issue which has been a factor that limits the performance of the semiconductor device 1, an efficient cooling system 10 may be used. For example, in a field of high performance computing (HPC) field and the semiconductor device 1 to which a stacked three-dimensional (3D) semiconductor chip is applied, the cooling system 10 may be needed to respond to an increased power density, a heat generation amount, etc. due to high degree of integration of the semiconductor device 1. Thus, the cooling system 10 using a liquid coolant may be included in the semiconductor device 1 according to an embodiment.

Hereinafter, a first direction (e.g., Z direction) may refer to a thickness direction of the semiconductor chip 100. A second direction (e.g., X direction) may refer to a direction from among directions parallel with an upper surface of the semiconductor chip 100, for example, a length direction. A third direction (e.g., Y direction) may refer to a direction perpendicular to the second direction (e.g., X direction) from among the directions parallel with the upper surface of the semiconductor chip 100, for example, a width direction.

Referring to FIGS. 1 to 5, the semiconductor device 1 according to an embodiment may include the semiconductor chip 100 including the substrate 110 extending along a plane (e.g., XY plane), a plurality of coolant chambers 200 that accommodate a coolant capable of cooling heat generated from the semiconductor chip 100, a plurality of nozzles 300 configured to spray the coolant accommodated in the plurality of coolant chambers 200 toward the substrate 110, and a plurality of actuators 400 configured to adjust internal pressure of the plurality of coolant chambers 200.

The semiconductor chip 100 according to an embodiment may include the substrate 110 and a semiconductor integrated circuit 120 provided on a surface of the substrate 110. An upper surface 101 of the semiconductor chip 100 may be an upper surface of the substrate 110, and the semiconductor integrated circuit 120 may be formed on a lower surface of the substrate 110. However, the disclosure is not limited thereto, and the upper surface 101 of the semiconductor chip 100 may be an upper surface of a thermal conductive surface provided on the substrate 110. In addition, the semiconductor integrated circuit 120 may be provided at any location in relation to the substrate 110, for example, between the upper surface and the lower surface of the substrate 110 (e.g., on or above the upper surface of the substrate 110and on or below the lower surface of the substrate 110). The semiconductor chip 100 may be various semiconductor integrated circuit chips. For example, the semiconductor chip 100 may be a memory chip including a memory integrated circuit, a logic chip including a logic integrated circuit, for example, a central processing unit (CPU) chip, a graphic processing unit (GPU) chip, an application specific integrated circuit (ASIC) chip, etc. To implement the semiconductor device 1 having a small form factor, the semiconductor chip 100 may be a semiconductor integrated circuit chip of a wafer level. The substrate 110 may be a wafer.

The semiconductor device 1 may include another semiconductor chip 100 arranged in a two-dimensional (2D) manner with respect to the semiconductor chip 100. In an example embodiment, although it is not shown in the drawings, other semiconductor chips 100 may be additionally arranged on both sides (e.g., left and right sides) of the semiconductor chip 100 in the second direction (e.g., X direction) and/or both sides (e.g., upper and lower sides) of the semiconductor chip 100 in the third direction (e.g., Y direction). For example, the semiconductor chip 100 may be a logic chip, and the other semiconductor chips 100 additionally arranged on both sides of the semiconductor chip 100 in the second direction (e.g., X direction) and/or the third direction (e.g., Y direction) may be a memory chip. For example, the additionally arranged semiconductor chip 100 may be a high-bandwidth memory, (HBM); however, the disclosure is not limited thereto.

A wiring (not shown) for electrical connection between the semiconductor integrated circuit 120 and a printed circuit board 1000 may be provided on a lower surface of the semiconductor chip 100. The wiring (not shown) may be electrically passivated against an outside. The semiconductor chip 100 may also be referred to as an integrated circuit die, and the semiconductor device 1 including an integrated circuit die may be referred to as an integrated circuit device.

The plurality of coolant chambers 200 may accommodate a coolant that is to be sprayed toward the substrate 110. For example, the plurality of coolant chambers 200 may be arranged apart from the substrate 110 at a certain distance in the first direction (e.g., Z direction) perpendicular to one plane (e.g., XY plane). According to an embodiment, when the substrate 110 includes the upper surface 101 extending along the plane (e.g., XY plane), the plurality of coolant chambers 200 may be arranged to face the upper surface 101. In this regard, the plurality of coolant chambers 200 may be arranged apart from each other along the plane (e.g., XY plane).

According to an embodiment, the arrangement of the plurality of coolant chambers 200 may be determined according to a plurality of cooling areas 130 of the semiconductor chip 100. For example, the semiconductor chip 100 may be divided into the plurality of cooling areas 130 along the plane (e.g., XY plane). For example, when the upper surface 101 of the semiconductor chip 100 is formed to be the same as the upper surface of the substrate 110, the upper surface of the substrate 110 may be divided into the plurality of cooling areas 130 each having a certain surface area. For example, the certain surface area of each of the plurality of cooling areas 130 may be about 0.25 mm² to about 30 mm².

According to an embodiment, the plurality of cooling areas 130 may include a plurality of tetragonal shapes having a certain length L in the second direction (e.g., X direction) and a width W in the third direction (e.g., Y direction). For example, the certain length L of each of the plurality of cooling areas 130 in the second direction (e.g., X direction) may be about 3 mm to about 20 mm. In addition, the certain width W of each of the plurality of cooling areas 130 in the third direction (e.g., Y direction) may be about 1 mm to about 18 mm. However, the disclosure is not limited thereto, and each of the plurality of cooling areas 130 may have a different size and a different shape according to a size and a shape of the heating area of the semiconductor chip 100. For example, some of the plurality of cooling areas 130 may have the same shape and the same size with each other, and some of the plurality of cooling areas 130 may have different shapes and different sizes from each other.

For example, as illustrated in FIG. 2, the plurality of cooling areas 130 may include nine cooling areas 131 to 139, and each of the nine cooling areas 131 to 139 may have a tetragonal shape having a certain length L in the second direction (e.g., X direction) and a certain width W in the third direction (e.g., Y direction). In this regard, the plurality of coolant chambers 200 may be arranged to correspond to the plurality of cooling areas 130. For example, the plurality of coolant chambers 200 may include nine coolant chambers 210 to 290 respectively corresponding to the nine cooling areas 131 to 139.

According to an embodiment, heating components included in the semiconductor chip 100, for example, the semiconductor integrated circuit 120 may be provided on or below some areas of the plurality of cooling areas 130. The heat generation amount of the semiconductor integrated circuit 120 may increase according to high performance computing (HPC), increased power density, and/or high integration degree of the semiconductor chip 100. Accordingly, among the plurality of cooling areas 130, a first heating temperature of a first cooling area in which a heating component is provided may be different from a second heating temperature of a second cooling area in which no heating component is provided. For example, a difference between the first heating temperature and the second heating temperature may be about 10° C. to about 30° C. However, the disclosure is not limited thereto, and the difference between the first heating temperature and the second heating temperature may vary according to a type of the heating component(s) included in the semiconductor chip 100.

According to an example embodiment described above, it may be understood that the heating component(s) included in the semiconductor chip 100 may be provided in one area of the plurality of cooling areas 130; however, the disclosure is not limited thereto. The heating component(s) included in the semiconductor chip 100 may be provided in two or more areas of the plurality of cooling areas 130. In addition, two or more heating components may be included in the semiconductor chip 100. In this regard, from among the plurality of cooling areas 130, the heating temperatures of the cooling areas in which different heating components are provided may be different from each other.

The plurality of nozzles 300 may respectively be provided on or below the plurality of coolant chambers 200 and spray the coolant accommodated in the plurality of coolant chambers 200 toward the substrate 110. For example, the plurality of nozzles 300 may respectively be provided on or below the plurality of coolant chambers 200. For example, as illustrated in FIG. 2, when the nine coolant chambers 210 to 290 are arranged, nine nozzles 310 to 390 may be arranged to respectively correspond to the nine coolant chambers 210 to 290. However, the disclosure is not limited thereto, and the nozzle may be arranged on or below some of the plurality of coolant chambers 200.

The plurality of nozzles 300 according to an embodiment may spray the coolant toward the substrate 110, more specifically, toward the plurality of cooling areas 130 into which the substrate 110 is divided. In addition, the plurality of nozzles 300 may spray the coolant accommodated in the plurality of coolant chambers 200 at a certain flow rate and in a certain flow amount. Moreover, the plurality of nozzles 300 may respectively be provided at central portions of corresponding cooling areas 130. For example, when the plurality of cooling areas 130 are divided to include the plurality of tetragonal shapes having a certain length L in the second direction (e.g., X direction) and a certain width W in the third direction (e.g., Y direction), each of the plurality of nozzles 300 may be provided at a central portion of each of the plurality of tetragonal shapes. However, the disclosure is not limited thereto. For example, each of the plurality of nozzles 300 may be provided to correspond to a location having a high heating temperature in each of the plurality of cooling areas 130.

As described above, the heating temperature of the plurality of cooling areas 130 may vary according to a type and location of the heating component provided corresponding thereto. Accordingly, a cooling capacity for cooling the plurality of cooling areas 130 may vary according to a heating temperature of each of the plurality of cooling areas 130.

The plurality of nozzles 300 according to an embodiment may spray the coolant at different flow rates and/or in different flow amounts from each other according to a heating temperature of each of the plurality of cooling areas 130. For example, when the internal pressures of the plurality of coolant chambers 200 where the plurality of nozzles 300 are respectively provided are adjusted to be different from one another, the flow rates and/or amounts of the coolant sprayed from the plurality of nozzles 300 may also be adjusted to be different from one another. As the flow rates and/or amounts of the coolant sprayed from the plurality of nozzles 300 are adjusted to be different from one another, the temperature of each of the plurality of cooling areas 130 may be adjusted individually.

Although the foregoing embodiment(s) describes the plurality of nozzles 300 as spraying devices capable of spraying the coolant accommodated in the plurality of coolant chambers 200, the disclosure is not limited thereto. For example, the plurality of nozzles 300 may be replaced with any spray devices capable of spraying the coolant accommodated in the plurality of coolant chambers 200 toward the plurality of cooling areas 130.

The plurality of actuators 400 may respectively be arranged on the plurality of coolant chambers 200 to individually adjust the internal pressures of the plurality of coolant chambers 200. For example, when the internal pressures of the plurality of coolant chambers 200 are adjusted individually, the flow rates and/or amounts of the coolant sprayed from the plurality of nozzles 300 may be adjusted to be different from each other. In other words, as the plurality of actuators 400 individually adjust the internal pressure of the plurality of coolant chambers 200, the flow rates and/or amounts of the coolant sprayed from the plurality of nozzles 300 may be adjusted to be different from each other.

The plurality of actuators 400 according to an embodiment may respectively be arranged on the plurality of coolant chambers 200. For example, as illustrated in FIG. 2, when the nine coolant chambers 210 to 290 are arranged, nine actuators 410 to 490 may be arranged to respectively correspond to the nine coolant chambers 210 to 290. However, the disclosure is not limited thereto, and one or more actuator(s) may be arranged on some of the plurality of coolant chambers 200 and not arranged on other plurality of coolant chambers 200.

The plurality of actuators 400 according to an embodiment may include at least one of a piezoelectric actuator and a thermal-jet actuator. However, the disclosure is not limited thereto, and the plurality of actuators 400 according to an embodiment may include any actuator capable of adjusting the internal pressure of the plurality of coolant chambers 200, for example, a capacitive actuator or a shape memory alloy actuator.

Methods of adjusting the flow rate and/or amount of the coolant sprayed from the plurality of nozzles 300 by adjusting the internal pressure of the plurality of coolant chambers 200 through the use of the plurality of actuators 400 according to example embodiments will be described below in relation to FIGS. 3 to 6C.

The coolant according to an embodiment may flow into a coolant inflow channel 810 through a coolant inflow port 800. For example, the coolant inflow port 800 may be a coolant inflow path in fluid communication with the coolant inflow channel 810. As illustrated in FIG. 2, the coolant inflow port 800 may include a plurality of coolant inflow ports and may be connected to each of a plurality of coolant inflow channels 811 to 813 included in the coolant inflow channel 810. However, the disclosure is not limited thereto, and the coolant inflow port 800 may include a single coolant inflow port and may further include a branch port in fluid communication with the plurality of coolant inflow channels 811 to 813.

The coolant inflow channel 810 may be provided to facilitate the fluid communication between the coolant inflow port 800 and the plurality of coolant chambers 200. Accordingly, the coolant introduced through the coolant inflow port 800 may flow into the plurality of coolant chambers 200 through the coolant inflow channel 810.

The coolant inflow channel 810 according to an embodiment may include a single coolant inflow channel or a plurality of coolant inflow channels. For example, the coolant inflow channel 810 may include a single coolant inflow channel and connect the coolant inflow port 800 to the plurality of coolant chambers 200. In this case, the coolant inflow channel 810 may include a flow path branched to be in fluid communication with each of the plurality of coolant chambers 200. A pump 900 may apply pressure to the coolant passing through the coolant inflow channel 810. The coolant to which the pressure is applied by the pump 900 may pass through the coolant inflow channel 810 and be accommodated in the plurality of coolant chambers 200.

According to an embodiment, the coolant accommodated in the plurality of coolant chambers 200 may be sprayed from the plurality of nozzles 300 in different flow amounts and/or at different flow rates by the plurality of actuators 400 described below. Accordingly, it may be unnecessary to adjust the pressure of the pump 900 to adjust the flow rate and amount of the coolant sprayed from the plurality of nozzles 300. In other words, the introduction of the coolant into the plurality of coolant chambers 200 may be distinguished from the spraying of the coolant from the plurality of coolant chambers 200. Accordingly, as the pump 900 only applies primary pressure such that the coolant introduced through the coolant inflow port 800 passes through the coolant inflow channel 810 and is accommodated in the plurality of coolant chambers 200, no micro-control of the pressure to adjust the flow rate and/or amount of the coolant sprayed from the plurality of nozzles 300 may be required. Thus, the convenience in designing the coolant inflow channel 810 and the plurality of coolant chambers 200 may be improved.

According to an embodiment, the coolant inflow channel 810 may include a plurality of coolant inflow channels and connect the coolant inflow port 800 to the plurality of coolant chambers 200. For example, as illustrated in FIG. 2, a plurality of first coolant chambers 210 to 230 may be arranged in the second direction (e.g., X direction) perpendicular to the first direction (e.g., Z direction). In addition, a plurality of second coolant chambers 240 to 260 and a plurality of third coolant chambers 270 to 290 may be arranged apart from the plurality of first coolant chambers 210 to 230 in the third direction (e.g., Y direction) perpendicular to the second direction (e.g., X direction).

A first coolant inflow channel 811 according to an embodiment may extend in the second direction (e.g., X direction) and may be configured to have fluid communication with each of the plurality of first coolant chambers 210 to 230. A second coolant inflow channel 812 may extend in the second direction (e.g., X direction) and may be in fluid communication with each of the plurality of second coolant chambers 240 to 260. A third coolant inflow channel 813 may extend in the second direction (e.g., X direction) and may be in fluid communication with each of the plurality of third coolant chambers 270 to 290. As described above, when the coolant inflow channel 810 includes a plurality of coolant inflow channels, the flow amounts of the coolant flowing into the plurality of coolant chambers arranged in each column may be controlled individually. Moreover, the plurality of coolant inflow channel 810 may be arranged not to interfere with each other, which leads to improved convenience in design.

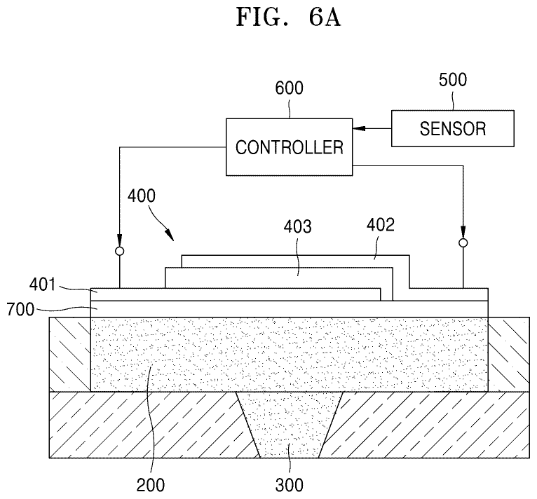

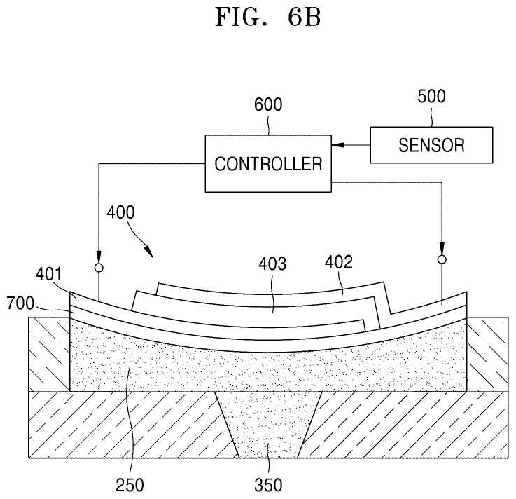

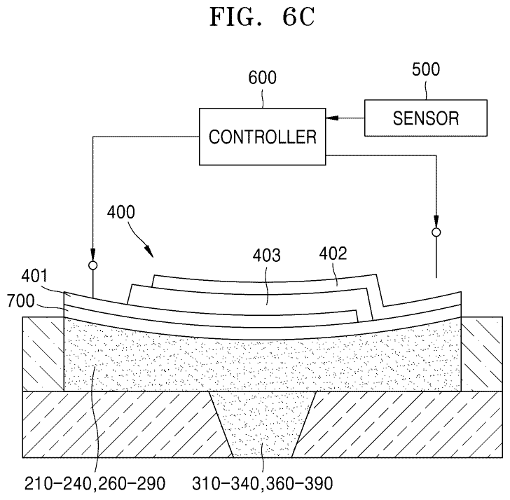

FIGS. 6A to 6C are each a schematic view of an actuator, a sensor, and a controller according to example embodiments.

Referring to FIGS. 2 to 6C, the semiconductor chip 100 according to an embodiment may include the substrate 110 and the semiconductor integrated circuit 120 provided on a surface of the substrate 110. In this regard, the substrate 110 may be divided into the nine cooling areas 131 to 139 in a tetragonal shape having a certain length L in the second direction (e.g., X direction) and a certain width W in the third direction (e.g., Y direction). The semiconductor integrated circuit 120 may be provided in a first cooling area 135 that is positioned at a center of the nine cooling areas 131 to 139. In this case, the semiconductor integrated circuit 120 may not be provided in second cooling areas 131 to 134 and 136 to 139.

The first heating temperature of the first cooling area 135 in which the semiconductor integrated circuit 120, which generates heat, is provided may be higher than the second heating temperature of the second cooling areas 131 to 134 and 136 to 139 in which the semiconductor integrated circuit 120 is not provided. According to an embodiment, a sensor 500 may measure temperature information of each of the plurality of cooling areas 130. For example, the sensor 500 may measure the first heating temperature of the first cooling area 135 and the second heating temperature of the second cooling areas 131 to 134 and 136 to 139.

Although areas in which the semiconductor integrated circuit 120, which generates heat, is not provided are described as the second cooling areas 131 to 134 and 136 to 139, and the temperature of the second cooling areas 131 to 134 and 136 to 139 is collectively referred to as the second heating temperature in the embodiments described above, the disclosure is not limited thereto. For example, the heating temperature of the second cooling areas 132, 134, 136, and 138 that are adjacent to the first cooling area 135 in which the semiconductor integrated circuit 120 generating heat is provided may be higher than the heating temperature of the second cooling areas 131, 133, 135, and 137 that are not adjacent to the first cooling area 135. In this regard, the sensor 500 may measure the temperature of each of the second cooling areas 131 to 134 and 136 to 139 individually.

A controller 600 may control operation of the plurality of actuators 400 according to temperature information measured by the sensor 500. For example, when the first heating temperature of the first cooling area 135 is measured to exceed the second heating temperature of the second cooling areas 131 to 134 and 136 to 139, an actuator 450 corresponding to the first cooling area 135 may increase a first internal pressure of a coolant chamber 250 arranged to face the first cooling area 135. In addition, actuators 410 to 440 and 460 to 490 corresponding to the second cooling areas 131 to 134 and 136 to 139 may increase a second internal pressure of coolant chambers 210 to 240 and 260 to 290 arranged to respectively face the second cooling areas 131 to 134 and 136 to 139. In this regard, the first internal pressure may be control to exceed the second internal pressure, and accordingly, a cooling capacity of the coolant sprayed from a nozzle 350 arranged to face the first cooling area 135 may be controlled to exceed a cooling capacity of the coolant sprayed from nozzles 310 to 340 and 360 to 390 that respectively face the second cooling areas 131 to 134 and 136 to 139.

According to an embodiment, when the plurality of actuators 400 are piezoelectric actuators illustrated in FIGS. 6A to 6C, a plurality of diaphragms 700 having elastic force may each be provided between each of the plurality of actuators 400 and each of the plurality of coolant chambers 200.

Each of the plurality of actuators 400 may include a first electrode 401, a second electrode 402, and a piezoelectric element layer 403 connected to the first electrode 401 and the second electrode 402. The piezoelectric element layer 403 may be transformed to have a certain curvature according to a control signal received from the controller 600.

For example, when the actuator 450 corresponding to the first cooling area 135 increases the first internal pressure of the coolant chamber 250 arranged to face the first cooling area 135, the piezoelectric element layer 403 included in the actuator 450 may transform the diaphragms 700 to reduce a volume of the coolant chamber 250 as illustrated in FIG. 6B.

In addition, the actuators 410 to 440 and 460 to 490 corresponding to the second cooling areas 131 to 134 and 136 to 139 may change the second internal pressure of the coolant chambers 210 to 240 and 260 to 290 arranged to face the second cooling areas 131 to 134 and 136 to 139. In this case, the second internal pressure may be changed to be lower than the first internal pressure. For example, as illustrated in FIG. 6C, the piezoelectric element layer 403 included in the actuators 410 to 440 and 460 to 490 may transform the diaphragms 700 to increase a volume of each the coolant chambers 210 to 240 and 260 to 290 such that the second internal pressure is changed to be lower than the first internal pressure. The adjustments of the first internal pressure and the second internal pressure as shown in FIGS. 6B and 6C may be both performed or one of the adjustments may be performed.

As described above, by using the change in the volume of the plurality of coolant chambers 200, the first internal pressure of the coolant chamber 250 may be controlled to exceed the second internal pressure of the coolant chambers 210 to 240 and 260 to 290. Accordingly, the cooling capacity of the coolant sprayed from the nozzle 350 arranged to face the first cooling area 135 may be controlled to exceed the cooling capacity of the coolant sprayed from the nozzles 310 to 340 and 360 to 390 arranged to face the second cooling areas 131 to 134 and 136 to 139. As the cooling capacity of the coolant sprayed to the first cooling area 135 is controlled to exceed the cooling capacity of the coolant sprayed to the second cooling areas 131 to 134 and 136 to 139, an excessive increase in temperature of a particular area of the substrate 110 may be prevented.

Although the areas in which the semiconductor integrated circuit 120, which generates heat, is not provided are described as the second cooling areas 131 to 134 and 136 to 139, and the temperature of the second cooling areas 131 to 134 and 136 to 139 is collectively referred to as the second heating temperature in the embodiments described above, the disclosure is not limited thereto. For example, the heating temperature of the second cooling areas 132, 134, 136, and 138 adjacent to the first cooling area 135 in which the semiconductor integrated circuit 120 generating heat is provided may be higher than the heating temperature of the second cooling areas 131, 133, 135, and 137 not adjacent to the first cooling area 135. In this case, the actuators 410 to 440 and 460 to 490 may individually control the cooling capacities of the coolant sprayed from the nozzles 310 to 340 and 360 to 390 by individually adjusting the internal pressures of the coolant chambers 210 to 240 and 260 to 290 according to the measured temperatures of the second cooling areas 131 to 134 and 136 to 139.

A coolant discharge channel 850 may be used to discharge the coolant which has cooled the plurality of cooling areas 130. For example, a coolant spray area M may be positioned between the semiconductor chip 100 and the plurality of coolant chambers 200 in the first direction (e.g., Z direction). The coolant discharge channel 850 may be configured to have fluid communication with the coolant spray area M and may be used to discharge the coolant from the coolant spray area M.

The coolant discharge channel 850 according to an embodiment may be configured to have fluid communication with a coolant discharge port 860. In this case, the pump 900 may apply pressure to the coolant passing through the coolant discharge channel 850 to discharge the coolant to the coolant discharge port 860 from the coolant discharge channel 850. The coolant which has passed through the coolant discharge port 860 may pass through a heat exchanger 910 and be cooled again. The coolant re-cooled through the heat exchanger 910 may be stored in a storage 920 and may be reused through the coolant inflow port 800 when the coolant is needed.

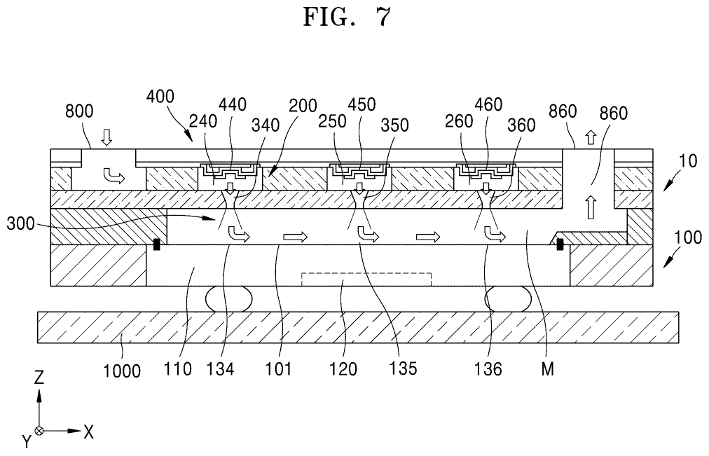

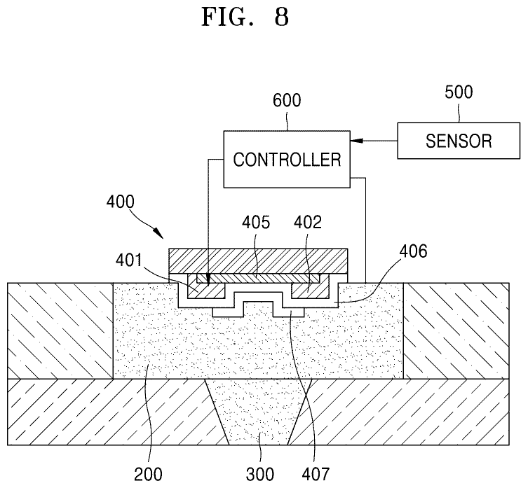

FIG. 7 is a cross-sectional view of the semiconductor device of FIG. 2 taken along line A-A. FIG. 8 is a schematic view of the actuator, the sensor, and the controller according to an example embodiment.

Referring to FIGS. 7 and 8, the plurality of actuators 400 according to an embodiment may be thermal-jet actuators. Components other than the plurality of actuators 400 may be substantially the same as the components illustrated in FIG. 3, and thus, any redundant description thereon is omitted.

For example, each of the plurality of actuators 400 may include the first electrode 401, the second electrode 402, a heat-generating heater 405 connected to the first electrode 401 and the second electrode 402, a protective layer 406, and an anti-cavitation layer 407. The heat-generating heater 405 may be heated to a certain temperature according to a control signal received from the controller 600. The protective layer 406 may include an insulating material which may protect the first and second electrodes 401 and 402 and the heat-generating heater 405 from the coolant. In addition, the anti-cavitation layer 407 may prevent damage which may be caused to the heat-generating heater 405 due to cavitation pressure generated during dissipation of bubbles and concentrated at a center of the heat-generating heater 405.

For example, the heat-generating heater 405 may include at least one of a tantalum nitride (TaN) and a tantalum-aluminum alloy (TaAI). In addition, the first electrode 401 and the second electrode 402 may include at least one of aluminum and aluminum alloy. The protective layer 406 may include a silicon nitride film. The anti-cavitation layer 407 may include tantalum (Ta). The materials described above are only an example, and the disclosure is not limited thereto.

According to an embodiment, the cooling capacity of the coolant sprayed to the first cooling area 135 in which the semiconductor integrated circuit 120 generating heat is provided may be controlled to exceed the cooling capacity of the coolant sprayed to the second cooling areas 134 and 136. Accordingly, the plurality of actuators 440 to 460 may be controlled such that the first internal pressure of the coolant chamber 250 corresponding to the first cooling area 135 exceeds the second internal pressure of the coolant chambers 240 and 260 corresponding to the second cooling areas 134 and 136.

For example, a pulse width of a first control signal transmitted to the heat-generating heater included in the actuator 450 corresponding to the coolant chamber 250 may exceed a pulse width of a second control signal transmitted to the heat-generating heater included in the actuators 440 and 460 corresponding to the coolant chambers 240 and 260. Accordingly, the cooling capacity of the coolant sprayed to the first cooling area 135 may be controlled to exceed the cooling capacity of the coolant sprayed to the second cooling areas 134 and 136.

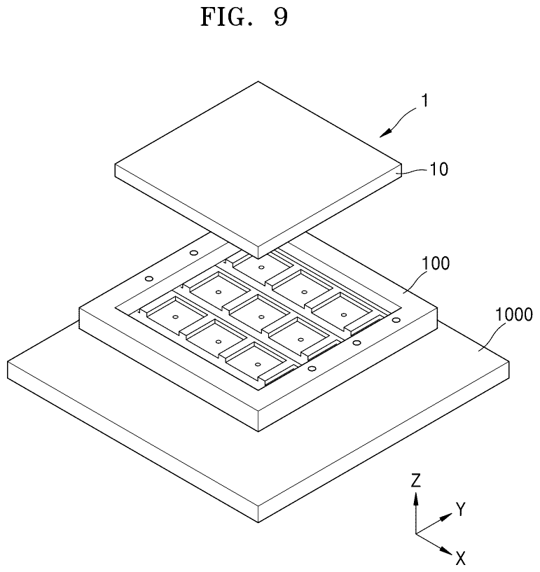

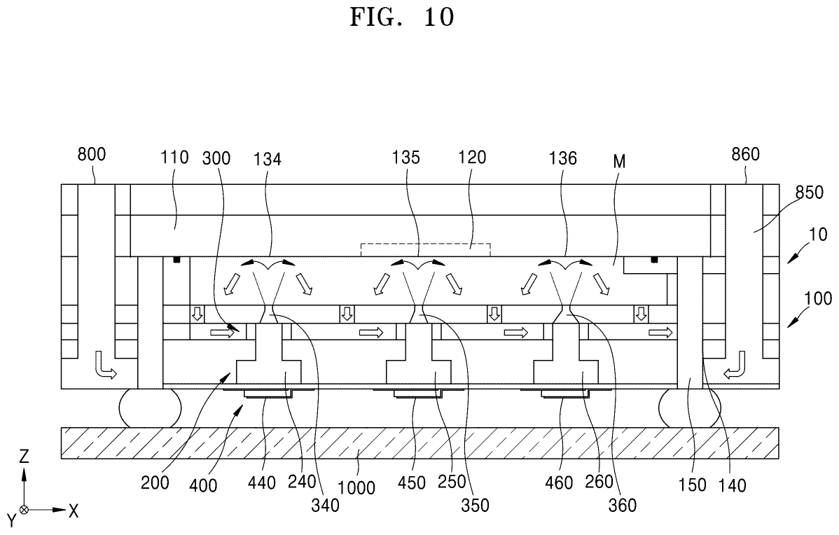

FIG. 9 is an exploded perspective view of the semiconductor device according to an example embodiment. FIG. 10 is a cross-sectional view of the semiconductor device according to an example embodiment.

Referring to FIGS. 9 and 10, features other than the arrangement of the plurality of coolant chambers 200, the plurality of nozzles 300, and the plurality of actuators 400 according to embodiments on a lower surface (or a lower portion) of the semiconductor chip 100 may be substantially the same as those illustrated in FIG. 3, and thus, any redundant description thereon is omitted.

According to an embodiment, as the plurality of coolant chambers 200, the plurality of nozzles 300, and the plurality of actuators 400 are arranged on the lower surface (or lower portion) of the semiconductor chip 100, the coolant spray area M to which the coolant is spayed between the substrate 110 and the plurality of coolant chambers 200 may be positioned on the lower surface (or lower portion) of the semiconductor chip 100.

A through hole 140 according to an embodiment may be provided between the semiconductor chip 100 and the printed circuit board 1000. For example, the through hole 140 may extend between the lower surface of the semiconductor chip 100 and the printed circuit board 1000 in the first direction (e.g., Z direction). A wiring 150 according to an embodiment may be provided in the through hole 140 to connect the printed circuit board 1000 to the semiconductor integrated circuit 120 included in the semiconductor chip 100. For example, the wiring 150 may include a conductive material which may facilitate electrical connection. Accordingly, the wiring 150 may electrically connect the printed circuit board 1000 to the semiconductor integrated circuit 120 included in the semiconductor chip 100.

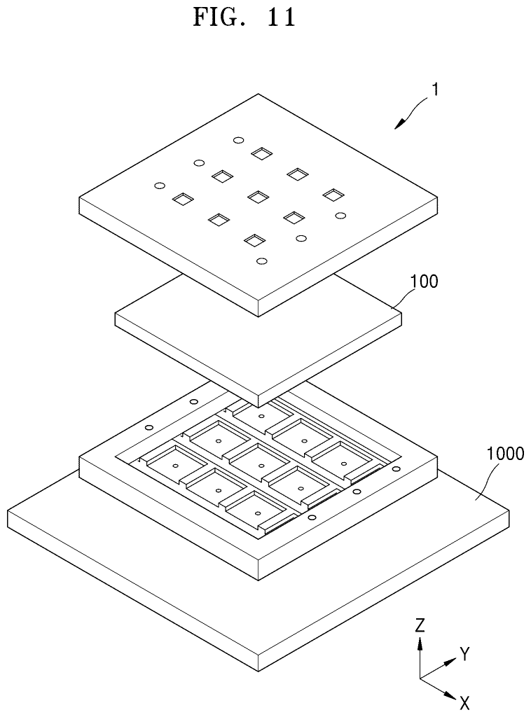

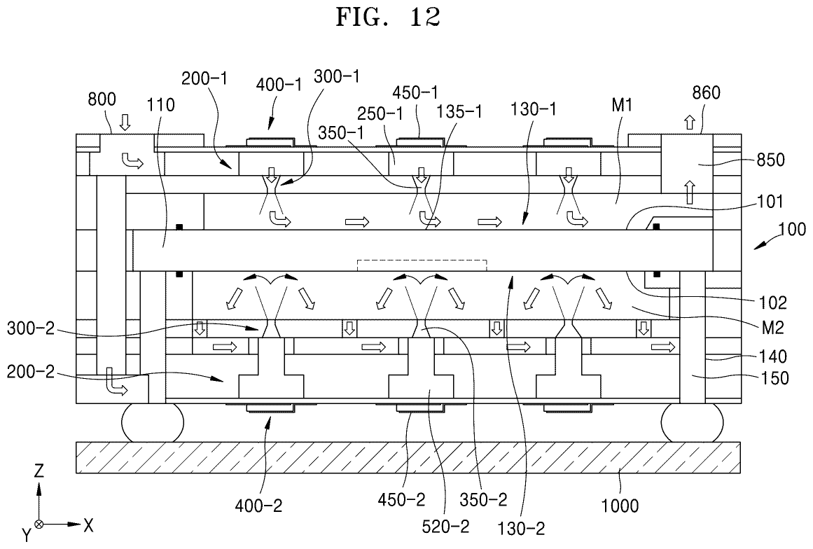

FIG. 11 is an exploded perspective view of the semiconductor device according to an example embodiment. FIG. 12 is a cross-sectional view of the semiconductor device according to an example embodiment.

Referring to FIGS. 11 and 12, the plurality of coolant chambers 200, the plurality of nozzles 300, and the plurality of actuators 400 may all be arranged on a first surface of the semiconductor chip 100, for example, the upper surface 101 and the second surface of the semiconductor chip 100, for example, the lower surface 102. Features other than the arrangement of the plurality of coolant chambers 200, the plurality of nozzles 300, and the plurality of actuators 400 on the upper surface 101 and the lower surface 102 of the semiconductor chip 100 may be substantially the same as those illustrated in FIGS. 3 and 9, and thus, any redundant description thereon is omitted.

According to an embodiment, the plurality of coolant chambers 200 may include a plurality of first coolant chambers 200-1 arranged to face the first surface 101 of the semiconductor chip 100 and a plurality of second coolant chambers 200-2 arranged to face the second surface 102 opposite to the first surface 101 of the semiconductor chip 100. The plurality of first coolant chambers 200-1 may be substantially the same as the plurality of coolant chambers 200 illustrated in FIG. 3, and the plurality of second coolant chambers 200-2 may be substantially the same as the plurality of coolant chambers 200 illustrated in FIG. 9, and thus, any redundant description thereon is omitted for convenience in explanation.

According to an embodiment, the plurality of nozzles 300 may include a plurality of first nozzles 300-1 respectively arranged on the plurality of first coolant chambers 200-1 and configured to spray the coolant to the first surface 101 of the semiconductor chip 100 and a plurality of second nozzles 300-2 respectively arranged on the plurality of second coolant chambers 200-2 and configured to spray the coolant to the second surface 102 of the semiconductor chip 100. The plurality of first nozzles 300-1 may be substantially the same as the plurality of nozzles 300 illustrated in FIG. 3, and the plurality of second nozzles 300-2 may be substantially the same as the plurality of nozzles 300 illustrated in FIG. 9, and thus, any redundant description thereon is omitted for convenience in explanation.

According to an embodiment, the plurality of actuators 400 may include a plurality of first actuators 400-1 respectively arranged on the plurality of first coolant chambers 200-1 and configured to individually adjust internal pressures of the plurality of first coolant chambers 200-1 and a plurality of second actuators 400-2 respectively arranged on the plurality of second coolant chambers 200-2 and configured to individually adjust internal pressures of the plurality of second coolant chambers 200-2. The plurality of first actuators 400-1 may be substantially the same as the plurality of actuators 400 illustrated in FIG. 3, and the plurality of second actuators 400-2 may be substantially the same as the plurality of actuators 400 illustrated in FIG. 10, and thus, any redundant description thereon is omitted for convenience in explanation.

The coolant according to an embodiment may flow into the coolant inflow channel 810 through the coolant inflow port 800. For example, the coolant inflow port 800 may be a coolant inflow path in fluid communication with the coolant inflow channel 810.

The coolant inflow channel 810 may be arranged to facilitate the fluid communication between the coolant inflow port 800 and the plurality of first coolant chambers 200-1 and between the coolant inflow port 800 and the plurality of second coolant chambers 200-2. Accordingly, the coolant introduced through the coolant inflow port 800 may flow into the plurality of first coolant chambers 200-1 and the plurality of second coolant chambers 200-2 through the coolant inflow channel 810.

The coolant inflow channel 810 according to an embodiment may include a flow path branched to be in fluid communication with the plurality of first coolant chambers 200-1 and the plurality of second coolant chambers 200-2. The pump 900 may apply pressure to the coolant passing through the coolant inflow channel 810. The coolant to which the pressure is applied by the pump 900 may pass through the coolant inflow channel 810 and be accommodated in the plurality of first coolant chambers 200-1 and the plurality of second coolant chambers 200-2.

The coolant inflow port 800, the coolant inflow channel 810, and the pump 900 may be substantially the same as the coolant inflow port 800 and the coolant inflow channel 810 illustrated in FIG. 2, except for the feature of fluid communication with the plurality of first coolant chambers 200-1 and the plurality of second coolant chambers 200-2, and thus, any redundant description thereon is omitted.

As the plurality of second coolant chambers 200-2, the plurality of second nozzles 300-2, and the plurality of second actuators 400-2 are arranged on the lower surface 102 of the semiconductor chip 100, a second coolant spray area M2 to which the coolant is spayed between the substrate 110 and the plurality of second coolant chambers 200-2 may be provided on the lower surface 102 of the semiconductor chip 100.

The through hole 140 according to an embodiment may be arranged between the semiconductor chip 100 and the printed circuit board 1000. For example, the through hole 140 may be arranged to extend between the lower surface 102 of the semiconductor chip 100 and the printed circuit board 1000 in the first direction (e.g., Z direction). The wiring 150 according to an embodiment may be arranged in the through hole 140 to connect the printed circuit board 1000 to the semiconductor integrated circuit 120 included in the semiconductor chip 100. For example, the wiring 150 may include a conductive material which may facilitate electrical connection. Accordingly, the wiring 150 may electrically connect the printed circuit board 1000 to the semiconductor integrated circuit 120 included in the semiconductor chip 100.

The first surface 101 of the semiconductor chip 100 according to an embodiment may be divided into a plurality of first cooling areas 130-1 having a length in the second direction (e.g., X direction) perpendicular to the first direction (e.g., Z direction) and a width in the third direction (e.g., Y direction) perpendicular to the first direction (e.g., Z direction) and the second direction (e.g., X direction), to correspond to each first nozzle included in the plurality of first nozzles 300-1. In addition, the second surface 102 of the semiconductor chip 100 may be divided into a plurality of second cooling areas 130-2 having a length in the second direction (e.g., X direction) and a width in the third direction (e.g., Y direction), to correspond to each second nozzle included in the plurality of second nozzles 300-2. Although FIG. 12 collectively denotes the plurality of first cooling areas 130-1 and the plurality of second cooling areas 130-2 without specifically showing divided plurality of first and second cooling areas 130-1, 130-2, it is assumed that the plurality of first cooling areas 130-1 and the plurality of second cooling areas 130-2 are divided to respectively correspond to the plurality of first nozzles 300-1 and the plurality of second nozzles 300-2.

According to an embodiment, the sensor 500 may measure temperature information of the plurality of first cooling areas 130-1 and the plurality of second cooling areas 130-2. For example, the sensor 500 may measure the heating temperature of the plurality of first cooling areas 130-1 arranged on the first surface 101 of the semiconductor chip 100 and the heating temperature of the plurality of second cooling areas 130-2 arranged on the second surface 102 of the semiconductor chip 100.

According to an embodiment, there may be a difference between the heating temperature of the cooling area in which the semiconductor integrated circuit 120 generating heat is provided and the heating temperature of the cooling area in which the semiconductor integrated circuit 120 is not provided. In addition, there may be a difference between the heating temperatures of the upper surface and the lower surface of the cooling area in which the semiconductor integrated circuit 120 generating heat is provided. For example, according to the arrangement location of the semiconductor integrated circuit 120 in the first direction (e.g., Z direction), there may be a difference between the heating temperature of an upper cooling area 135-1 in which the semiconductor integrated circuit 120 is arranged and the heating temperature of a lower cooling area 135-2. The sensor 500 may measure the temperatures of the upper cooling area 135-1 and the lower cooling area 135-2 individually.

The controller 600 may control the operation of the plurality of first actuators 400-1 and the plurality of second actuators 400-2 according to the temperature information measured by the sensor 500. For example, when the heating temperature of the lower cooling area 135-2 is measured to exceed the heating temperature of the upper cooling area 135-1, an actuator 450-2 corresponding to the lower cooling area 135-2 may increase a first internal pressure of a coolant chamber 250-2 arranged to face the lower cooling area 135-2. In addition, an actuator 450-1 corresponding to the upper cooling area 135-1 may increase the internal pressure of a coolant chamber 250-1 arranged to face the upper cooling area 135-1. In this case, the internal pressure of the coolant chamber 250-2 may be controlled to exceed the internal pressure of the coolant chamber 250-1, and accordingly, the cooling capacity of the coolant sprayed from a nozzle 350-2 arranged to face the lower cooling area 135-2 may be controlled to exceed the cooling capacity of the coolant sprayed from a nozzle 350-1 arranged to face the upper cooling area 135-1.

The coolant discharge channel 850 may discharge the coolant which has cooled the plurality of first cooling areas 130-1 and the plurality of second cooling areas 130-2 to the outside. For example, a first coolant spray area M1 may be arranged between the upper surface 101 of the semiconductor chip 100 and the plurality of first coolant chambers 200-1 in the first direction (e.g., Z direction). In addition, the second coolant spray area M2 may be arranged between the lower surface 102 of the semiconductor chip 100 and the plurality of second coolant chambers 200-2 in the first direction (e.g., Z direction). The coolant discharge channel 850 may be configured to have fluid communication with the first coolant spray area M1 and the second coolant spray area M2 and may discharge the coolant from the first coolant spray area M1 and the second coolant spray area M2.

The coolant discharge channel 850 according to an embodiment may be configured to have fluid communication with the coolant discharge port 860. In this case, the pump 900 may apply pressure to the coolant passing through the coolant discharge channel 850 to discharge the coolant to the coolant discharge port 860 from the coolant discharge channel 850. The coolant which has passed through the coolant discharge port 860 may pass through the heat exchanger 910 and be cooled again. The coolant re-cooled through the heat exchanger 910 may be stored in the storage 920 and may be reused through the coolant inflow port 800 when the coolant is needed.

According to an embodiment, a semiconductor device employing a liquid cooling structure may be provided.

According to an embodiment, a semiconductor device including a cooling structure having different cooling capacities corresponding to heating areas having different temperature ranges may be provided.

According to an embodiment, a semiconductor device having improved cooling efficiency by including a cooling structure having different cooling capacities corresponding to heating areas having different temperature ranges may be provided.

According to an embodiment, provided is a semiconductor device having improved cooling efficiency by including a cooling structure individually operating in correspondence to heating areas having different temperature ranges may be provided.

It should be understood that example embodiments described herein should be considered in a descriptive sense only and not for purposes of limitation. Descriptions of features or aspects within each embodiment should typically be considered as available for other similar features or aspects in other embodiments. While one or more example embodiments have been described with reference to the figures, it will be understood by those of ordinary skill in the art that various changes in form and details may be made therein without departing from the spirit and scope as defined by the following claims and their equivalents.

What is claimed is:

1. A semiconductor device comprising:
a semiconductor chip including a substrate, the substrate extending along a plane;
a plurality of coolant chambers spaced apart from the substrate at a certain distance in a first direction, each coolant chamber of the plurality of coolant chambers being configured to accommodate a coolant, the first direction being perpendicular to the plane;
a plurality of nozzles respectively provided on or below the plurality of coolant chambers and configured to spray the coolant toward the substrate; and
a plurality of actuators respectively provided on the plurality of coolant chambers and configured to individually adjust internal pressures of the plurality of coolant chambers.

2. The semiconductor device of claim 1, wherein the plurality of coolant chambers are spaced apart from each other along a direction parallel to the plane.

3. The semiconductor device of claim 1, wherein the semiconductor chip includes a plurality of cooling areas along the plane, and
wherein each cooling area of the plurality of cooling areas has a surface area of about 0.25 mm² to about 30 mm².

4. The semiconductor device of claim 1, wherein the semiconductor chip is divided into a plurality of cooling areas, each cooling area having a certain length in a second direction and a certain width in a third direction, to correspond to each nozzle included in the plurality of nozzles, the second direction being perpendicular to the first direction and the third direction being perpendicular to the first direction and the second direction.

5. The semiconductor device of claim 4, wherein the certain length of each cooling area of the plurality of cooling areas in the second direction is about 3 mm to about 20 mm, and
wherein the certain width of each cooling area of the plurality of cooling areas in the third direction is about 1 mm to about 18 mm.

6. The semiconductor device of claim 4, wherein a heating component included in the semiconductor chip is positioned to correspond to at least one of the plurality of cooling areas.

7. The semiconductor device of claim 4, wherein the plurality of actuators are further configured to adjust an internal pressure of a corresponding coolant chamber based on a first heating temperature of a first cooling area of the plurality of cooling areas and a second heating temperature of a second cooling area of the plurality of cooling areas.

8. The semiconductor device of claim 7, wherein the plurality of actuators are further configured to adjust the internal pressure of the corresponding coolant chamber based on a difference between the first heating temperature and the second heating temperature being about 10° C. to about 30° C.

9. The semiconductor device of claim 4, further comprising:
a sensor configured to measure temperatures of the plurality of cooling areas; and
a controller configured to control operations of the plurality of actuators based on temperature information measured by the sensor.

10. The semiconductor device of claim 1, further comprising:
a coolant inflow port through which the coolant is introduced;
a coolant inflow channel configured to have a fluid communication with each coolant chamber of the plurality of coolant chambers and introduce the coolant, introduced through the coolant inflow port, into the plurality of coolant chambers; and
a pump configured to apply a pressure to the coolant passing through the coolant inflow channel.

11. The semiconductor device of claim 10, wherein the coolant inflow channel includes a plurality of coolant inflow channels, and
wherein the plurality of coolant inflow channels include:
a first coolant inflow channel configured to have a fluid communication with a plurality of first coolant chambers arranged in a second direction, the second direction being perpendicular to the first direction; and
a second coolant inflow channel configured to have a fluid communication with a plurality of second coolant chambers arranged apart from the plurality of first coolant chambers in a third direction, the third direction being perpendicular to the second direction.

12. The semiconductor device of claim 1, wherein the coolant is sprayed toward a coolant spray area between the plurality of coolant chambers and the semiconductor chip, and
wherein the semiconductor device further comprises:
a coolant discharge channel configured to have a fluid communication with the coolant spray area and discharge the coolant from the coolant spray area; and
a pump configured to apply a pressure to the coolant passing through the coolant discharge channel.

13. The semiconductor device of claim 1, wherein the plurality of actuators include piezoelectric actuators, and
wherein the semiconductor device further comprises a plurality of diaphragms respectively provided between the plurality of actuators and the plurality of coolant chambers.

14. The semiconductor device of claim 1, wherein the plurality of actuators include thermal-jet actuators.

15. The semiconductor device of claim 1, wherein the plurality of coolant chambers include a plurality of first coolant chambers, arranged to face a first surface of the semiconductor chip, and a plurality of second coolant chambers, arranged to face a second surface of the semiconductor chip, the second surface being opposite to the first surface,
wherein the plurality of nozzles include a plurality of first nozzles, provided respectively corresponding to the plurality of first coolant chambers to spray a first coolant toward the first surface of the semiconductor chip, and a plurality of second nozzles, provided respectively corresponding to the plurality of second coolant chambers to spray a second coolant toward the second surface of the semiconductor chip, and
wherein the plurality of actuators include a plurality of first actuators, provided respectively corresponding to the plurality of first coolant chambers and configured to individually adjust internal pressures of the plurality of first coolant chambers, and a plurality of second actuators, provided respectively corresponding to the plurality of second coolant chambers and configured to individually adjust internal pressures of the plurality of second coolant chambers.

16. The semiconductor device of claim 15, further comprising:
a printed circuit board arranged to face the second surface of the semiconductor chip;
a through hole provided between the printed circuit board and the semiconductor chip; and
a wiring provided in the through hole and configured to electrically connect the printed circuit board to the semiconductor chip.

17. The semiconductor device of claim 15, further comprising:
a coolant inflow port through which the coolant is introduced;
a coolant inflow channel configured to have a fluid communication with the plurality of first coolant chambers and the plurality of second coolant chambers and introduce the coolant, introduced through the coolant inflow port, into the plurality of first coolant chambers and the plurality of second coolant chambers; and
a pump configured to apply a pressure to the coolant passing through the coolant inflow channel.

18. The semiconductor device of claim 15, wherein the first surface of the semiconductor chip is divided into a plurality of first cooling areas, each first cooling area having a length in a second direction and a width in a third direction, to correspond to each first nozzle included in the plurality of first nozzles, the second direction being perpendicular to the first direction and the third direction being perpendicular to the first direction and the second direction, and
wherein the second surface of the semiconductor chip is divided into a plurality of second cooling areas, each second cooling area having a length in the second direction and a width in the third direction, to correspond to each second nozzle included in the plurality of second nozzles.

19. The semiconductor device of claim 18, further comprising:
a sensor configured to measure a temperature of each first cooling area of the plurality of first cooling areas and each second cooling area of the plurality of second cooling areas; and
a controller configured to control operations of the plurality of first actuators and the plurality of second actuators based on temperature information measured by the sensor.

20. The semiconductor device of claim 15, wherein the first coolant is sprayed toward a first coolant spray area between the plurality of first coolant chambers and the semiconductor chip, and the second coolant is sprayed toward a second coolant spray area between the plurality of second coolant chambers and the semiconductor chip, and
wherein the semiconductor device further includes:
a coolant discharge channel configured to have a fluid communication with the first coolant spray area and the second coolant spray area and discharge the first coolant and the second coolant from the first coolant spray area and the second coolant spray area; and
a pump configured to apply a pressure to the first coolant and the second coolant passing through the coolant discharge channel.
